(19) United States
(12) Patent Application Publication
(10) Pub. No.: US 2025/0024694 A1
(43) Pub. Date: Jan. 16, 2025

(54) IMAGING DEVICE

(71) Applicant: Panasonic Intellectual Property Management Co., Ltd., Osaka (JP)

(72) Inventors: KENICHI AOYAMA, Osaka (JP); HIROAKI IIJIMA, Nara (JP); YUUKO TOMEKAWA, Osaka (JP)

(21) Appl. No.: 18/898,737

(22) Filed: Sep. 27, 2024

Related U.S. Application Data
(63) Continuation of application No. PCT/JP2023/011086, filed on Mar. 22, 2023.

(30) Foreign Application Priority Data
Apr. 11, 2022 (JP) 2022-065289

(51) Int. Cl. H10K 39/32

(52) U.S. Cl. CPC H10K 39/32

(57) ABSTRACT

An imaging device includes a pixel electrode having a top surface and a bottom surface facing the top surface, a photoelectric conversion layer that is in contact with the top surface and converts light into electric charge, and a top electrode that faces the top surface of the pixel electrode with the photoelectric conversion layer interposed therebetween. The pixel electrode contains a nitride of a first metal, and a second metal different from the first metal. The nitride of the first metal is a main component of the pixel electrode. A concentration of the second metal in a first three-dimensional region including the top surface is higher than a concentration of the second metal in a second three-dimensional region including the bottom surface. The first three-dimensional region does not include the bottom surface, and the second three-dimensional region does not include the top surface.

### BACKGROUND

### 1. Technical Field

The present disclosure relates to an imaging device.

### 2. Description of the Related Art

An image sensor is an element that includes light detection devices that generate electrical signals in response to the amount of incident light, pixels arranged in one or two dimensions, a signal detection circuit that detects the electrical signals, and various elements for the correct operation of these elements. Among image sensors, a multilayer image sensor is an image sensor that has, as a pixel, a light detection device with a structure in which a pixel electrode, a photoelectric conversion layer, and a top electrode are stacked in order from the substrate side. Examples of the multilayer image sensor are disclosed in Japanese Unexamined Patent Application Publication Nos. 2014-60315, 2015-12239, 2015-225950, 2008-263178, and 2011-71469, and International Publication No. 2017/081847.

### SUMMARY

Existing pixel electrodes form a natural oxide film on their surfaces when exposed to the atmosphere. Since a natural oxide film is formed in an uncontrolled environment, the thickness and quality of the natural oxide film will vary. This causes variations in the drive voltage characteristics of the imaging device, resulting in a problem in that the reliability of the imaging device is low.

One non-limiting and exemplary embodiment provides a highly reliable imaging device with suppressed variations in characteristics.

In one general aspect, the techniques disclosed here feature an imaging device including a pixel electrode having a first plane and a second plane that faces the first plane, a photoelectric converter that is in contact with the first plane and converts light into electric charge, and a counter electrode that faces the first plane of the pixel electrode with the photoelectric converter interposed therebetween. The pixel electrode contains a nitride of a first metal, and a second metal different from the first metal. The nitride of the first metal is a main component of the pixel electrode. A concentration of the second metal in a first three-dimensional region including the first plane is higher than a concentration of the second metal in a second three-dimensional region including the second plane. The first three-dimensional region does not include the second plane, and the second three-dimensional region does not include the first plane.

According to the present disclosure, highly reliable imaging devices with suppressed variations in characteristics can be supplied.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating the correlation between a larger diameter of a silicon wafer and improved mass production capacity regarding image sensors;

FIG. 2 is a diagram for illustrating the concerns caused by wafer transfer in air between a pixel electrode formation process and a photoelectric conversion layer formation process;

FIG. 3 is a circuit diagram illustrating the circuit configuration of an image sensor according to an embodiment;

FIG. 4 is a cross-sectional view of a device structure of a unit pixel cell of the image sensor according to the embodiment;

FIG. 5 is a cross-sectional view of the image sensor according to the embodiment;

FIG. 6A is a cross-sectional view of a pixel electrode of the image sensor according to the embodiment;

FIG. 6B is a cross-sectional view of a pixel electrode of an image sensor according to a comparative example;

FIG. 7 is a diagram illustrating a threshold voltage defined in the image sensor according to the embodiment;

FIG. 8A is a diagram illustrating the composition of the pixel electrode of the image sensor according to the embodiment;

FIG. 8B is a diagram illustrating the composition of the pixel electrode of the image sensor according to the comparative example;

FIG. 9 is a diagram illustrating the Al composition of the pixel electrode of the image sensor according to the embodiment;

FIG. 10 is a diagram illustrating the relationships between parasitic light sensitivity and applied voltage for the image sensors according to the embodiment and comparative example;

FIG. 11A is a cross-sectional view of a step in a manufacturing method of the image sensor according to the embodiment;

FIG. 11B is a cross-sectional view of a step in the manufacturing method of the image sensor according to the embodiment;

FIG. 11C is a cross-sectional view of a step in the manufacturing method of the image sensor according to the embodiment;

FIG. 11D is a cross-sectional view of a step in the manufacturing method of the image sensor according to the embodiment;

FIG. 11E is a cross-sectional view of a step in the manufacturing method of the image sensor according to the embodiment;

FIG. 12A is a cross-sectional view of a step in the manufacturing method of the image sensor according to the embodiment;

FIG. 12B is a cross-sectional view of a step in the manufacturing method of the image sensor according to the embodiment; and

FIG. 13 is a cross-sectional view of a step in the manufacturing method of the image sensor according to the embodiment.

### DETAILED DESCRIPTIONS

### (Underlying Knowledge Forming Basis of the Present Disclosure)

The present inventors have found that the following problems arise with the existing image sensors described in the “Description of the Related Art” section.

Hitherto, Si image sensors formed using Si, an inorganic material, as the photoelectric conversion material have been known. In contrast, to improve light detection sensitivity or to freely adjust the detection wavelength range, multilayer image sensors formed using organic materials or inorganic materials such as III-V inorganic compounds, perovskite structures, or quantum dots as photoelectric conversion materials have also been proposed.

In a multilayer image sensor, the circuit portion and the photoelectric conversion layer function independently, which increases the degree of freedom of the device structure. Thus, it is possible to fabricate high-performance image sensors using structures that cannot be achieved with Si image sensors. In the following, an organic image sensor will be described that uses organic materials as photoelectric conversion materials as an example. The present disclosure is applicable to multilayer image sensors in general and is not limited to organic image sensors.

An important factor in the industrial mass production of image sensors is the efficient and low-cost mass production of chips. One way to improve this productivity is to increase the diameters of silicon wafers used as substrates.

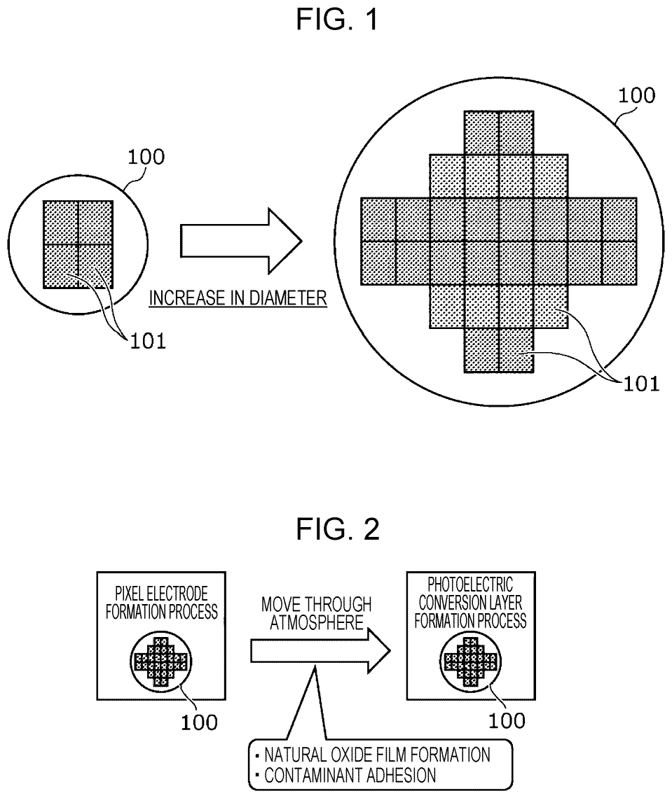

FIG. 1 is a diagram illustrating the correlation between a larger diameter of a silicon wafer 100 and improved mass production capacity regarding image sensors 101. As illustrated in FIG. 1, as the diameter of the silicon wafer 100 becomes larger, the number of image sensors 101 obtained by the same process increases. In other words, the production capacity per hour can be improved.

When manufacturing image sensors, which are multilayer image sensors, the formation of the pixel electrodes and photoelectric conversion layer may be separated from the patterning thereof. For example, in a case where organic materials are used as photoelectric conversion materials to manufacture image sensors 101, the organic materials cannot withstand the cleaning processes or heating temperatures previously used in the fabrication of semiconductor devices. Therefore, it is necessary to separate a pixel electrode formation process from a photoelectric conversion layer formation process. However, having factors that make it difficult to control conditions prior to the formation using organic materials is a factor that can worsen the yield of multilayer image sensors.

In the case of mass production of image sensors using organic materials as photoelectric conversion materials, Japanese Unexamined Patent Application Publication No. 2011-71469 proposes the use of a metal nitride as electrodes from the viewpoint of the adhesion property of films containing photoelectric conversion materials. However, various problems may arise due to atmospheric exposure involved in a case where the pixel electrode formation process is separated from the photoelectric conversion layer formation process.

FIG. 2 is a diagram for illustrating the concerns caused by wafer transfer in air between the pixel electrode formation process and the photoelectric conversion layer formation process. As illustrated in FIG. 2, there may be a case where the silicon wafer 100 is exposed to the atmosphere when the process proceeds from the pixel electrode formation process to the photoelectric conversion layer formation process. This atmospheric exposure is particularly a concern in a case where organic materials are used as photoelectric conversion materials because organic materials are prone to react with oxygen, ozone, and moisture, for example.

Specifically, as illustrated in FIG. 2, a natural oxide film may form on the surfaces of the electrodes, or there may be a risk of contaminant adhesion. It has also been confirmed that the metal nitride contained in the electrodes forms a film in the form of columnar crystals.

The natural oxide film is formed under uncontrolled conditions. It is thus expected that heterogeneity or defects in the natural oxide film are present. Moreover, in the columnar crystals of the metal nitride, it is difficult to uniformly control the inter-crystal voids. Under these conditions, variations in the drive voltage characteristics of each device fabricated within the plane of the silicon wafer 100 and a decrease in yield have been confirmed.

In light of the above-described problems, it is preferable that the formation and patterning of the pixel electrodes and photoelectric conversion layer be performed in an environment that does not degrade the light detection function during the manufacturing steps of multilayer image sensors to avoid atmospheric exposure. In general, however, significantly large manufacturing equipment is required to perform all of these formation and patterning under an inert atmosphere or vacuum.

Therefore, the present inventors provide a highly reliable imaging device in which the effect of a natural oxide film, even in a case where the natural oxide film is formed on the pixel electrodes after the formation of the pixel electrodes through exposure to the atmosphere, is suppressed and variations in the characteristics are suppressed. The present inventors also propose an imaging device that is easy to handle during the manufacturing steps.

For example, an imaging device according to an aspect of the present disclosure includes a pixel electrode having a first plane and a second plane that faces the first plane, a photoelectric converter that is in contact with the first plane and converts light into electric charge, and a counter electrode that faces the first plane of the pixel electrode with the photoelectric converter interposed therebetween. The pixel electrode contains a nitride of a first metal, and a second metal different from the first metal. The nitride of the first metal is a main component of the pixel electrode. A concentration of the second metal in a first three-dimensional region including the first plane is higher than a concentration of the second metal in a second three-dimensional region including the second plane. The first three-dimensional region does not include the second plane, and the second three-dimensional region does not include the first plane.

This allows the inclusion of the second metal in the natural oxide film present on the surface of the pixel electrode to suppress a surface state that is present on the surface of the natural oxide film to trap electrons or holes. Furthermore, the second metal fills the voids in the crystals that constitute the pixel electrode, so that the characteristics of the pixel electrode can be made uniform. This makes it easier to handle the silicon wafer during the manufacturing steps because the effect of atmospheric exposure can be suppressed even in the process that includes the step of exposure to the atmosphere when the process is switched from the pixel electrode formation process to the photoelectric conversion layer formation process. Variations in the characteristics of each imaging device within the plane of the silicon wafer can also be reduced.

In a case where the work function of the second metal is lower than that of the first metal, it is expected, due to this, that the parasitic light sensitivity of the imaging device can be reduced. For example, aluminum (Al), which can be used as the second metal, has a lower work function than, for example, titanium (Ti) and tantalum (Ta), which can be used as the first metal. Thus, the parasitic light sensitivity of the imaging device can be reduced.

For example, the second metal may be Al.

Al can be introduced using common semiconductor deposition methods such as an atomic layer deposition (ALD) method, sputtering, and an evaporation method. Even in a case where the deposited Al oxide film is to be removed, common removal processes such as dry etching or wet etching can be used. In addition, even if Al diffuses, its effect on the transistor is small, and thus highly reliable imaging devices with suppressed variations in characteristics can be realized.

For example, the pixel electrode may contain oxygen at the first plane.

This allows the second metal or its oxide to suppress variations in the characteristics of the pixel electrode, even in a case where the pixel electrode contains oxygen due to the natural oxide film.

For example, the first metal may be Ti.

Titanium nitride is conductive and has excellent barrier properties. Titanium nitride also has an excellent adhesion property to films containing organic materials formed on the top surface of the pixel electrode. In a case where copper (Cu) is used as a plug connected to the bottom surface of the pixel electrode, Cu diffusion can be effectively suppressed. This can suppress the degradation of the characteristics of the image sensor.

For example, the elemental concentration of the second metal in the first three-dimensional region may be greater than or equal to 0.5% and less than or equal to 10%.

As a result, since the second metal element concentration is greater than or equal to 0.5%, an effect in suppressing variations in characteristics due to the second metal can be fully realized. In addition, an increase in the elemental concentration of the second metal with a lower work function is expected to improve the parasitic light sensitivity reduction effect. On the other hand, if the content of the second metal is too large, the electrical characteristics of the pixel electrode may be degraded. However, when the elemental concentration of the second metal is less than or equal to 10%, the degradation of the characteristics of the pixel electrode can be suppressed.

For example, the pixel electrode may include a first layer that contains the nitride of the first metal, and a second layer that contains the first metal. The first layer and the second layer may be stacked in this order in a direction from the first plane toward the second plane.

This allows the diffusion of the second metal to be suppressed by the second layer. By suppressing the diffusion of the second metal into layers other than the pixel electrode, the degradation of the characteristics of the imaging device can be suppressed.

For example, the elemental concentration of the second metal in the second three-dimensional region may be less than or equal to 0.5%.

This allows the elemental concentration of the second metal in the second three-dimensional region to be sufficiently small. Thus, by suppressing the diffusion of the second metal into layers other than the pixel electrode, the degradation of the characteristics of the imaging device can be suppressed.

For example, the photoelectric converter may contain an organic material.

As a result, the light detection sensitivity can be improved, and the detection wavelength range can be freely adjusted.

In the following, embodiments will be specifically described with reference to the drawings.

Note that any one of the embodiments described below is intended to represent a general or specific example. Numerical values, shapes, constituent elements, arrangement positions and connection forms of the constituent elements, steps, and the order of steps are examples, and are not intended to limit the present disclosure. Among the constituent elements of the following embodiments, constituent elements that are not described in independent claims will be described as optional constituent elements.

Each drawing is a schematic diagram and is not necessarily precisely illustrated. Thus, for example, the scale and other details do not necessarily match in each drawing. In each drawing, substantially the same constituent elements are denoted by the same reference signs. Redundant description will be omitted or simplified.

In this specification, terms indicating relationships between elements, such as perpendicular, and the shapes of elements, such as rectangular, as well as numerical ranges are not expressions that express only the strict meaning, but expressions that also include substantially equivalent ranges, for example, differences of a few percent.

In this specification, the terms “above” and “below” do not refer to above (vertically above) and below (vertically below) in absolute spatial perception, but are used as terms defined by relative positional relationships based on the stacking order in the multilayer configuration. The terms “above” and “below” are applied to not only a case where two constituent elements are spaced apart from each other with another constituent element present therebetween, but also a case where two constituent elements are arranged in close contact with each other so as to be in contact with each other.

### Embodiments

### [Image Sensor Circuit Configuration]

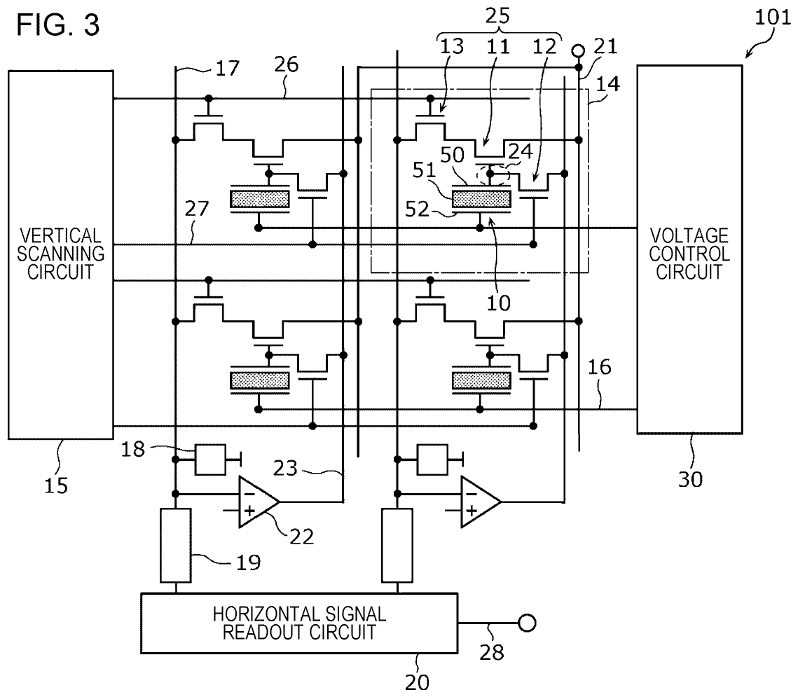

First, a summary of an image sensor 101, which is an example of an imaging device according to the present embodiment, will be described. FIG. 3 is a diagram illustrating a circuit configuration of the image sensor 101. As illustrated in FIG. 3, the image sensor 101 has unit pixel cells 14 and peripheral circuitry.

The unit pixel cells 14 are arranged on a semiconductor substrate in two dimensions, namely in a row direction and a column direction, to form a pixel region. In this specification, the row direction and column direction refer to the directions in which rows and columns extend, respectively. That is, the vertical direction is the column direction, and the horizontal direction is the row direction. Note that the unit pixel cells 14 may be arranged in one dimension, namely along one direction. That is, the image sensor 101 may be a line sensor.

Each unit pixel cell 14 includes a light detection unit 10 and an electric charge detection circuit 25. The electric charge detection circuit 25 includes an amplification transistor 11, a reset transistor 12, and an address transistor 13. The light detection unit 10 includes a pixel electrode 50, a photoelectric conversion layer 51, and a top electrode 52. The specific configuration of the light detection unit 10 will be described later.

The image sensor 101 has voltage control elements to apply a predetermined voltage to the top electrode 52. The voltage control elements include, for example, a voltage control circuit, a voltage generation circuit such as a constant voltage source, and a voltage reference line such as a ground line. The voltage applied by the voltage control elements is referred to as a control voltage. In the present embodiment, the image sensor 101 has a voltage control circuit 30 as a voltage control element.

The voltage control circuit 30 may generate a constant control voltage or may generate control voltages of different values. For example, the voltage control circuit 30 may generate a control voltage that changes continuously within a predetermined range. The voltage control circuit 30 determines the value of the control voltage to be generated, on the basis of a command from the operator operating the image sensor 101 or a command from, for example, another control unit of the image sensor 101, and generates the control voltage having the determined value. The voltage control circuit 30 is provided, as part of the peripheral circuitry, outside a photosensitive region.

For example, the voltage control circuit 30 generates two or more different control voltages, and applies the two or more different control voltages to the top electrode 52, so that the spectral sensitivity characteristics of the photoelectric conversion layer 51 change. The changes in spectral sensitivity characteristics include the spectral sensitivity characteristic where the sensitivity of the photoelectric conversion layer 51 to light to be detected is zero. Accordingly, for example, while the detection signals are read out row by row from the unit pixel cells 14, the control voltage that causes the sensitivity of the photoelectric conversion layers 51 to be zero is applied from the voltage control circuit 30 to the top electrodes 52. As a result, the effect of light incident when the detection signals are read out can be reduced to almost zero in the image sensor 101. Thus, global shutter operation can be virtually achieved even when the detection signals are read out row by row.

In the present embodiment, as illustrated in FIG. 3, the voltage control circuit 30 applies a control voltage via counter electrode signal lines 16 to the top electrodes 52 of the unit pixel cells 14 arranged in the row direction. This changes the voltage between the pixel electrode 50 and top electrode 52 of each unit pixel cell 14, thereby switching the spectral sensitivity characteristics in the light detection unit 10. Alternatively, the voltage control circuit 30 achieves an electronic shutter operation by applying a control voltage to obtain a spectral sensitivity characteristic having zero sensitivity to light at a predetermined timing during image capture. Note that the voltage control circuit 30 may apply a control voltage to the pixel electrode 50.

To irradiate the light detection unit 10 with light to accumulate electrons as signal charge on the pixel electrode 50, the pixel electrode 50 is set to a higher potential relative to the top electrode 52. This causes electrons to move toward the pixel electrode 50. In this case, the current flows from the pixel electrode 50 toward the top electrode 52 since the direction of electron movement is opposite. To irradiate the light detection unit 10 with light to accumulate holes as signal charge on the pixel electrode 50, the pixel electrode 50 is set to a lower potential relative to the top electrode 52. This causes holes to move toward the pixel electrode 50. In this case, the current flows from the top electrode 52 toward the pixel electrode 50.

The pixel electrode 50 is connected to the gate electrode of the amplification transistor 11, and the signal charge collected by the pixel electrode 50 is stored in an electric charge storage node 24, which is located between the pixel electrode 50 and the gate electrode of the amplification transistor 11. In the present embodiment, the signal charge is holes, but the signal charge can also be electrons.

The signal charge stored in the electric charge storage node 24 is applied to the gate electrode of the amplification transistor 11 as a voltage corresponding to the amount of signal charge. The amplification transistor 11 is included in the electric charge detection circuit 25 and amplifies the voltage applied to the gate electrode. The address transistor 13 selectively reads out the amplified voltage as the signal voltage. The address transistor 13 is also referred to as a row selection transistor. The reset transistor 12, one of whose source or drain is connected to the pixel electrode 50, resets the signal charge stored in the electric charge storage node 24. In other words, the reset transistor 12 resets the potential of the gate electrode of the amplification transistor 11 and the potential of the pixel electrode 50.

To selectively perform the operations described above in the unit pixel cells 14, the image sensor 101 includes a power supply line 21, vertical signal lines 17, address signal lines 26, and reset signal lines 27. These wiring and signal lines are connected to the individual unit pixel cells 14. Specifically, in each unit pixel cell 14, the power supply line 21 is connected to either the source or the drain of the amplification transistor 11. The vertical signal line 17 is connected to either the source or the drain of the address transistor 13. The address signal line 26 is connected to the gate electrode of the address transistor 13. The reset signal line 27 is connected to the gate electrode of the reset transistor 12.

The peripheral circuitry includes a vertical scanning circuit 15, a horizontal signal readout circuit 20, column signal processing circuits 19, load circuits 18, differential amplifiers 22, and the voltage control circuit 30. The vertical scanning circuit 15 is also referred to as a row scanning circuit. The horizontal signal readout circuit 20 is also referred to as a column scanning circuit. The column signal processing circuits 19 are also referred to as row signal storage circuits. The differential amplifiers 22 are also referred to as feedback amplifiers.

The vertical scanning circuit 15 is connected to the address signal lines 26 and the reset signal lines 27. The vertical scanning circuit 15 selects unit pixel cells 14 arranged in each row on a row-by-row basis to read out signal voltages and reset the potentials of the pixel electrodes 50. The power supply line 21 functions as a source follower power supply and supplies a predetermined power supply voltage to each unit pixel cell 14. The horizontal signal readout circuit 20 is electrically connected to the column signal processing circuits 19. The column signal processing circuits 19 are electrically connected, via the respective vertical signal lines 17 corresponding to the columns, to the unit pixel cells 14 arranged in each column. The load circuits 18 are electrically connected to the respective vertical signal lines 17. The load circuits 18 and the amplification transistors 11 form source follower circuits.

The differential amplifiers 22 are provided for the respective columns. The negative input terminals of the differential amplifiers 22 are connected to the corresponding vertical signal lines 17. The output terminals of the differential amplifiers 22 are connected to the unit pixel cells 14 of the individual rows via the feedback lines 23 corresponding to the individual rows.

The vertical scanning circuit 15 applies row selection signals, which control the on and off of the address transistors 13, to the gate electrodes of the address transistors 13 through the address signal lines 26. As a result, a scan is performed to select the target row to be read out. The signal voltages are read out from the unit pixel cells 14 of the selected row to the vertical signal lines 17. The vertical scanning circuit 15 applies reset signals, which control the on and off of the reset transistors 12, to the gate electrodes of the reset transistors 12 through the reset signal lines 27. This selects the row of unit pixel cells 14 to be subject to the reset operation. The vertical signal lines 17 transfer the signal voltages read out from the unit pixel cells 14 selected by the vertical scanning circuit 15 to the column signal processing circuits 19.

The column signal processing circuits 19 perform noise suppression signal processing, a typical example of which is correlated double sampling, and analog-to-digital conversion (AD conversion).

The horizontal signal readout circuit 20 sequentially reads out signals from the column signal processing circuits 19 to a horizontal common signal line 28.

Each differential amplifier 22 is connected via the feedback line 23 to either the drains or the sources of the reset transistors 12 that are not connected to the pixel electrodes 50. Thus, the differential amplifier 22 receives, from the negative input terminal, the output value of an address transistor 13 among the address transistors 13 when the address transistor 13 and the corresponding reset transistor 12 are in a conducting state. The differential amplifier 22 performs a feedback operation so that the gate potential of the amplification transistor 11 becomes a predetermined feedback voltage. In this case, the output voltage value of the differential amplifier 22 is 0 V or a positive voltage near 0 V. The feedback voltage means the output voltage of the differential amplifier 22.

### [Unit Pixel Cell Configuration]

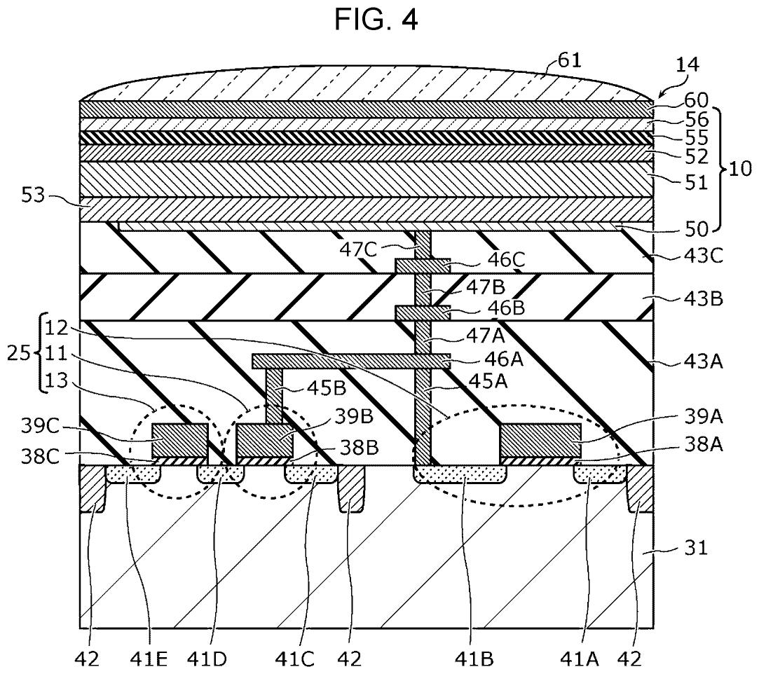

In the following, the detailed device structure of the unit pixel cells 14 of the image sensor 101 will be described using FIG. 4.

FIG. 4 is a schematic cross-sectional view of a cross section of the device structure of each unit pixel cell 14 of the image sensor 101 according to the present embodiment. Note that, in the cross-sectional view illustrated in FIG. 4, the shading representing a cross section is omitted for a semiconductor substrate 31 and interlayer insulating layers 43A, 43B, and 43C to prevent the drawing from becoming more complex.

As illustrated in FIG. 4, the unit pixel cell 14 includes the semiconductor substrate 31, the electric charge detection circuit 25, and the light detection unit 10. The semiconductor substrate 31 is, for example, a p-type silicon substrate. The electric charge detection circuit 25 detects the signal charge collected by the pixel electrode 50 and outputs a signal voltage. The electric charge detection circuit 25 includes the amplification transistor 11, the reset transistor 12, and the address transistor 13, and at least part of the electric charge detection circuit 25 is formed in the semiconductor substrate 31.

The amplification transistor 11 is formed in and on the semiconductor substrate 31. The amplification transistor 11 includes n-type impurity regions 41C and 41D, a gate insulating layer 38B, and a gate electrode 39B. The n-type impurity regions 41C and 41D function as drain and source, respectively. The gate electrode 39B is located on the gate insulating layer 38B. The gate insulating layer 38B is located on the semiconductor substrate 31.

The reset transistor 12 is formed in and on the semiconductor substrate 31. The reset transistor 12 includes n-type impurity regions 41B and 41A, a gate insulating layer 38A, and a gate electrode 39A. The n-type impurity regions 41B and 41A function as drain and source, respectively. The gate electrode 39A is located on the gate insulating layer 38A. The gate insulating layer 38A is located on the semiconductor substrate 31.

The address transistor 13 is formed in and on the semiconductor substrate 31. The address transistor 13 includes n-type impurity regions 41D and 41E, a gate insulating layer 38C, and a gate electrode 39C. The n-type impurity regions 41D and 41E function as drain and source, respectively. The gate electrode 39C is located on the gate insulating layer 38C. The gate insulating layer 38C is located on the semiconductor substrate 31.

Each of the amplification transistor 11, the reset transistor 12, and the address transistor 13 is, for example, a metal oxide semiconductor field-effect transistor (MOSFET). Each of the amplification transistor 11, the reset transistor 12, and the address transistor 13 is an n-channel MOSFET but may also be a p-channel MOSFET.

The gate insulating layers 38A, 38B, and 38C are each formed using insulating materials. For example, the gate insulating layers 38A, 38B, and 38C have a single-layer structure formed by a silicon oxide film or a silicon nitride film or a multilayer structure formed by these films.

The gate electrodes 39A, 39B, and 39C are each formed using conductive materials. For example, the gate electrodes 39A, 39B, and 39C are formed using polysilicon, which is given conductivity by adding impurities. Alternatively, the gate electrodes 39A, 39B, and 39C may be formed using a metal material such as copper.

The n-type impurity regions 41A, 41B, 41C, 41D, and 41E are formed by doping the semiconductor substrate 31 with n-type impurities, such as phosphorus (P), by means of ion implantation. In the example illustrated in FIG. 4, the n-type impurity region 41D is shared by the amplification transistor 11 and the address transistor 13. This connects the amplification transistor 11 and the address transistor 13 in series. Note that the n-type impurity region 41D may be separated into two n-type impurity regions. These two n-type impurity regions may be electrically connected via a wiring layer.

In the semiconductor substrate 31, device separation regions 42 are provided between the unit pixel cell 14 and its adjacent unit pixel cells 14 and between the amplification transistor 11 and the reset transistor 12. The device separation regions 42 provide electrical separation between the unit pixel cell 14 and its adjacent unit pixel cells 14. Moreover, the device separation regions 42 suppress leakage of the signal charge stored in the electric charge storage nodes 24. The device separation regions 42 are formed, for example, by doping the semiconductor substrate 31 with a high concentration of p-type impurities.

A multilayer wiring structure is provided on the top surface of the semiconductor substrate 31. The multilayer wiring structure includes interlayer insulating layers, one or more wiring layers, one or more plugs, and one or more contact plugs. Specifically, the interlayer insulating layers 43A, 43B, 43C are stacked in this order on the top surface of the semiconductor substrate 31.

In the interlayer insulating layer 43A, a contact plug 45A, a contact plug 45B, a wiring line 46A, and a plug 47A are buried. The contact plug 45A is connected to the n-type impurity region 41B of the reset transistor 12. The contact plug 45B is connected to the gate electrode 39B of the amplification transistor 11. The wiring line 46A connects the contact plug 45A and the contact plug 45B to each other. As a result, the n-type impurity region 41B, which functions as the drain of the reset transistor 12, is electrically connected to the gate electrode 39B of the amplification transistor 11.

In the interlayer insulating layer 43B, a wiring line 46B and a plug 47B are buried. The plug 47B is connected to the plug 47A via the wiring line 46B. In the interlayer insulating layer 43C, a wiring line 46C and a plug 47C are buried. The plug 47C is connected to the plug 47B via the wiring line 46C. The plug 47C is connected to the pixel electrode 50. As a result, the electric charge collected by the pixel electrode 50 flows through the plug 47C, the wiring line 46C, the plug 47B, the wiring line 46B, the plug 47A, the wiring line 46A, and the contact plug 45A in this order, and is stored in the n-type impurity region 41B. Note that not only the n-type impurity region 41B but also the plug 47C, the wiring line 46C, the plug 47B, the wiring line 46B, the plug 47A, the wiring line 46A, the contact plug 45A, the contact plug 45B, and the gate electrode 39B each function as an electric charge storage region.

The light detection unit 10 is provided on the interlayer insulating layer 43C. The light detection unit 10 includes the pixel electrode 50, the photoelectric conversion layer 51, the top electrode 52, and a functional layer 53. The photoelectric conversion layer 51 and the functional layer 53 are sandwiched between the top electrode 52 and the pixel electrode 50. The light detection unit 10 also has a protection layer 55 formed on at least part of the top surface of the top electrode 52. The light detection unit 10 further has a pixel protection film 56 covering the top surface of the protection layer 55. Note that the protection layer 55 and the pixel protection film 56 do not have to be provided. The detailed structure of the light detection unit 10 will be described later.

As illustrated in FIG. 4, the unit pixel cell 14 includes a color filter 60 and a microlens 61. The color filter 60 is provided above the top electrode 52 of the light detection unit 10. The microlens 61 is provided on the color filter 60. Note that the color filter 60 and the microlens 61 do not have to be provided.

In the present embodiment, the photoelectric conversion layer 51 and top electrode 52 of each unit pixel cell 14 are connected to the photoelectric conversion layers 51 and top electrodes 52 of the adjacent unit pixel cells 14, respectively, to form a single integrated photoelectric conversion layer 51 and a single integrated top electrode 52. Note that the photoelectric conversion layers 51 may be separated for the individual unit pixel cells 14. The top electrodes 52 for each row or column of the two-dimensionally arranged unit pixel cells 14 may be connected to form a single top electrode 52. In contrast, the pixel electrode 50 of each unit pixel cell 14 is not connected to the pixel electrodes 50 of the adjacent unit pixel cells 14 and is independent.

Note that the image sensor 101 may detect changes in the capacitance of the photoelectric conversion layer 51 without detecting electric charge from photoelectric conversion. This type of image sensor is disclosed in, for example, International Publication No. 2017/081847. That is, the photoelectric conversion layer 51 may generate hole-electron pairs in response to the intensity of incident light, or the capacitance of the photoelectric conversion layer 51 may change in response to the intensity of incident light. The image sensor 101 can detect light incident on the photoelectric conversion layer 51 by detecting the electric charge generated by the photoelectric conversion layer 51 or changes in the capacitance of the photoelectric conversion layer 51.

### [Structure of Light Detection Unit]

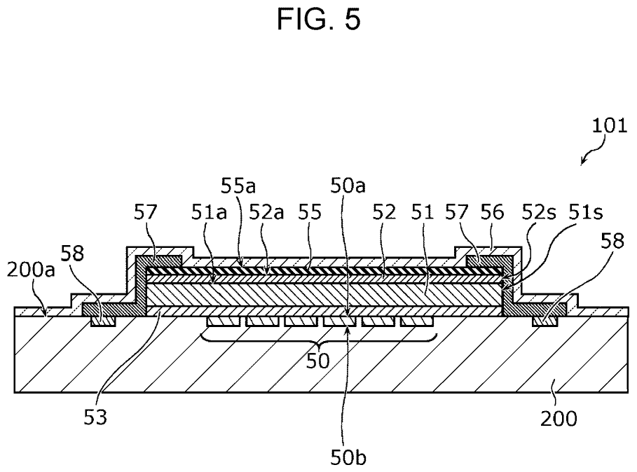

Next, a detailed structure of the light detection unit 10 will be described using FIG. 5.

FIG. 5 is a cross-sectional view of the image sensor 101 according to the present embodiment. In FIG. 5, the illustration of the constituent elements located below the interlayer insulating layer 43C is simplified or omitted. Specifically, the semiconductor substrate 31 and the interlayer insulating layers 43A, 43B, and 43C illustrated in FIG. 4 are collectively illustrated as a substrate 200, and the illustration of the wiring layers, gate electrodes, gate insulating layers, and impurity regions, for example, is omitted. The illustration of the color filters 60 and microlenses 61 is also omitted.

The image sensor 101 includes pixel electrodes 50, a photoelectric conversion layer 51, a functional layer 53, and a top electrode 52 as illustrated in FIG. 5. Moreover, the image sensor 101 further includes metal connectors 57 and control electrodes 58. The pixel electrodes 50 and the control electrodes 58 form part of the circuitry formed in the substrate 200. The metal connectors 57 form part of the counter electrode signal line 16.

The pixel electrodes 50 are arranged in a one-dimensional or two-dimensional array and buried in the substrate 200 so that each top surface 50a is exposed at a top surface 200a of the substrate 200. The pixel electrodes 50 are provided so as to correspond to the individual unit pixel cells 14. Each pixel electrode 50 connects the electric charge detection circuit 25 and the light detection unit 10 with each other.

The pixel electrode 50 has the top surface 50a and a bottom surface 50b. The top surface 50a is an example of a first plane. The bottom surface 50b is an example of a second plane and is a surface opposite the top surface 50a. Specifically, the bottom surface 50b is a surface closer to the semiconductor substrate 31 than the top surface 50a is.

The pixel electrode 50 contains a nitride of a first metal as its main component. The first metal is, for example, titanium (Ti). Alternatively, the first metal may be tantalum (Ta). For example, the pixel electrode 50 contains titanium nitride (TiN) or tantalum nitride (TaN) as its main component.

The pixel electrode 50 contains a second metal that is different from the first metal. The second metal is, for example, aluminum (Al). Alternatively, the second metal may be hafnium (Hf). The second metal is mainly contained in the vicinity of the top surface 50a of the pixel electrode 50. The second metal may be introduced as an oxide into the pixel electrode 50. The second metal is, for example, a metal with a lower work function than the first metal. The difference in work function between the first metal and the second metal is, for example, greater than or equal to 0.1 eV.

The pixel electrode 50 also contains oxygen at the top surface 50a. A metal oxide film may be formed on the top surface 50a. In the present embodiment, the pixel electrode 50 has a multilayer structure including a metal nitride layer and a metal layer. This specific configuration of the pixel electrode 50 will be described later.

The photoelectric conversion layer 51 is an example of a photoelectric converter that converts light into electric charge. The photoelectric conversion layer 51 is arranged on the top surface 200a of the substrate 200 so as to cover the pixel electrodes 50. The photoelectric conversion layer 51 is, for example, a layer that functions to generate electrons and holes in response to the amount and wavelength of incident light.

The photoelectric conversion layer 51 is, for example, an organic photoelectric conversion film formed using organic semiconductor materials. The photoelectric conversion layer 51 may include one or more organic semiconductor layers. Organic p-type and organic n-type semiconductors that are known materials can be used as materials contained in the organic semiconductor layers. The photoelectric conversion layer 51 may contain, for example, a composite material of organic and inorganic materials having a perovskite structure or a group III-V inorganic compound, and may contain indium gallium arsenide. The photoelectric conversion layer 51 may be, for example, a quantum dot photoelectric conversion film formed using inorganic materials.

The top electrode 52 is arranged on the photoelectric conversion layer 51. The top electrode 52 is a counter electrode that faces the top surface 50a of the pixel electrode 50 with the photoelectric conversion layer 51 interposed therebetween. The top electrode 52 covers a top surface 51a of the photoelectric conversion layer 51 so as to cover at least a region of the photoelectric conversion layer 51 corresponding to the region where the pixel electrodes 50 are provided. In the present embodiment, the top electrode 52 is formed to cover the entirety of the top surface 51a of the photoelectric conversion layer 51.

The top electrode 52 is arranged on the light incident side of the photoelectric conversion layer 51. Thus, the top electrode 52 is translucent to light to be photoelectrically converted by the photoelectric conversion layer 51. For example, the top electrode 52 is highly translucent to the visible or infrared light band. Specifically, the top electrode 52 is a transparent electrode formed using, for example, a transparent conductive oxide such as indium tin oxide (ITO), aluminum-doped zinc oxide (AZO), or gallium-doped zinc oxide (GZO).

The functional layer 53 is located between the photoelectric conversion layer 51 and the pixel electrode 50. The functional layer 53 is, for example, a layer inserted for the purpose of improving the light detection function. The functional layer 53 is, for example, a carrier transport layer that transports electrons or holes, a blocking layer that blocks carriers, or a carrier transport and blocking layer.

The functional layer 53 is formed using, for example, organic semiconductor materials. Organic p-type and organic n-type semiconductors that are known materials can be used as an organic semiconductor material contained in the functional layer 53. As long as the material functions as described above, the material contained in the functional layer 53 need not be limited to organic semiconductors. For example, the functional layer 53 may be formed using an inorganic oxide, or using materials including organic semiconductor materials and inorganic oxides.

The insertion position of the functional layer 53 is not limited to between the photoelectric conversion layer 51 and the pixel electrode 50. For example, the functional layer 53 may be provided between the top electrode 52 and the photoelectric conversion layer 51, depending on the desired function. Alternatively, the functional layer 53 may be inserted both between the top electrode 52 and the photoelectric conversion layer 51 and between the photoelectric conversion layer 51 and the pixel electrode 50. In FIGS. 4 and 5, a case where the functional layer 53 is inserted between the photoelectric conversion layer 51 and the pixel electrode 50 is illustrated as an example of insertion of the functional layer 53; however, the present disclosure is not limited to this case.

The protection layer 55 is formed to cover at least part of a top surface 52a of the top electrode 52. The protection layer 55 covers the top surface 52a so as to cover, for example, at least a region of the top electrode 52 corresponding to the region where the pixel electrodes 50 are provided.

The pixel protection film 56 covers the metal connectors 57 and the protection layer 55 and is provided on the top surface 200a of the substrate 200. The pixel protection film 56 is provided to cover the entire top surface 200a of the substrate 200.

The protection layer 55 and the pixel protection film 56 are formed using insulating materials. The protection layer 55 and the pixel protection film 56 help to prevent the photoelectric conversion layer 51 from being exposed to air and moisture. For example, the protection layer 55 is formed using Al₂O₃, for example. The pixel protection film 56 is formed using silicon oxide, silicon nitride, silicon oxynitride, or organic or inorganic polymer materials. The protection layer 55 and the pixel protection film 56 are highly translucent to light of wavelengths to be detected by the image sensor 101.

The metal connectors 57 are bonded to the control electrodes 58 and the top electrode 52 and electrically connect the control electrodes 58 and the top electrode 52 with each other. Specifically, the metal connectors 57 are bonded to the control electrodes 58 exposed at the top surface 200a of the substrate 200 and to side surfaces 52s of the top electrode 52. The metal connectors 57 further cover side surfaces 51s of the photoelectric conversion layer 51. The metal connectors 57 cover part of a top surface 55a of the protection layer 55 other than the region where the pixel electrodes 50 are provided. The bonding area between each metal connector 57 and the corresponding control electrode 58 may be larger than, smaller than, or the same as the bonding area between the metal connector 57 and the top electrode 52.

The metal connectors 57 contain metal. For example, the metal connectors 57 are formed of titanium, titanium nitride, aluminum, silicon, copper-doped aluminum (AlSiCu), copper, tungsten, gold, silver, nickel, cobalt, or alloys thereof. The metal connectors 57 may have a single-layer structure formed by a film containing metal among the above-described metals, or may have a multilayer structure including metal layers.

Note that, in the top view of the image sensor 101, the photoelectric conversion layer 51 and the top electrode 52 have a rectangular shape in the present embodiment. The control electrodes 58 are arranged in close vicinity to two of the four edges of the top electrode 52. Thus, the image sensor 101 is provided such that two metal connectors 57 cover the two respective edges of the top electrode 52. The two metal connectors 57 are bonded to the control electrodes 58 and the side surfaces 52s of the top electrode 52 to electrically connect the control electrodes 58 and the top electrode 52 to each other.

The control electrodes 58 contain metal and block light. For example, the control electrodes 58 are formed of titanium, titanium nitride, aluminum, silicon, copper-doped aluminum, copper, tungsten, or alloys thereof. The control electrodes 58 may have a single-layer structure formed by a film containing metal among the above-described metals, or may have a multilayer structure including metal layers.

### [Specific Configuration of Pixel Electrode]

Next, the specific configuration of the pixel electrode 50 of the image sensor 101 according to the present embodiment will be described in comparison with a comparative example.

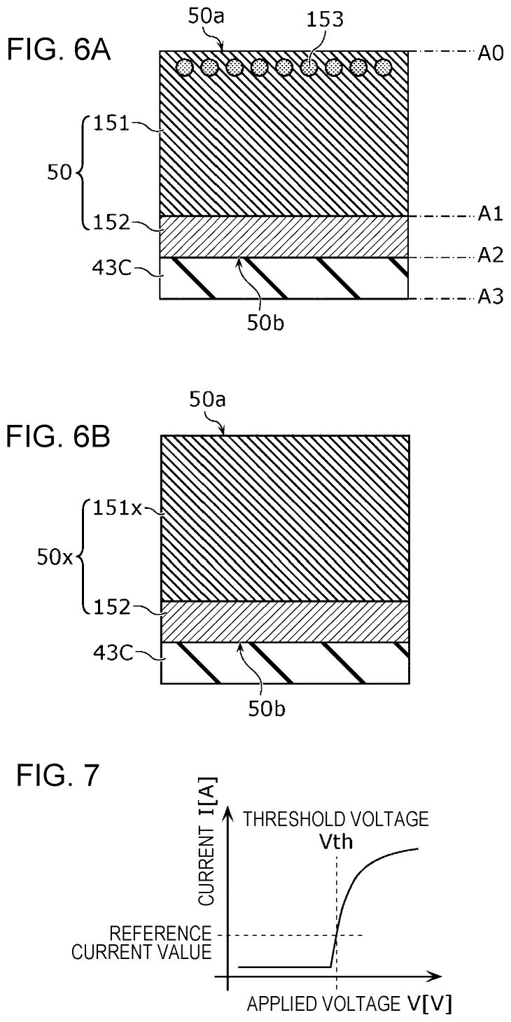

FIG. 6A is a cross-sectional view of the pixel electrode 50 of an image sensor according to an embodiment. FIG. 6B is a cross-sectional view of a pixel electrode 50x of an image sensor according to the comparative example. The pixel electrode 50x according to the comparative example has substantially the same configuration as the pixel electrode 50 according to the embodiment, but the composition of an element in the vicinity of the top surface 50a is different.

The following describes examples in which the pixel electrodes 50 and 50x include multiple layers, respectively, in both the embodiment and comparative example.

As illustrated in FIG. 6A, the pixel electrode 50 according to the embodiment includes a metal nitride layer 151 and a metal layer 152. The metal nitride layer 151 and the metal layer 152 are stacked in this order in the direction from the top surface 50a toward the bottom surface 50b.

The metal nitride layer 151 is an example of a first layer, which contains a nitride of a first metal. The metal nitride layer 151 is located on the upper layer side of the pixel electrode 50. The top surface of the metal nitride layer 151 is the top surface 50a of the pixel electrode 50. The metal nitride layer 151 is, for example, a TiN layer but may also be a TaN layer.

The metal layer 152 is an example of a second layer, which contains the first metal. The metal layer 152 is located on the lower layer side of the pixel electrode 50. The bottom surface of the metal layer 152 is the bottom surface 50b of the pixel electrode 50. The metal layer 152 is a Ti layer but may also be a Ta layer.

The metal nitride layer 151 according to the embodiment contains a metallic element 153, which is an example of the second metal. FIG. 6A schematically illustrates the metallic element 153. The metallic element 153 is mostly contained in the surface portion of the metal nitride layer 151. The metallic element 153 exists as single atoms or as oxides. The metallic element 153 is, for example, Al.

The metallic element 153 is introduced into the surface portion of the metal nitride layer 151 by depositing, as a dense thin film, an oxide of the metallic element 153 after depositing TiN, which is the main component of the metal nitride layer 151. The dense thin film is formed using, for example, an atomic layer deposition (ALD) method or the like.

In contrast, as illustrated in FIG. 6B, the pixel electrode 50x according to the comparative example includes a metal nitride layer 151x instead of the metal nitride layer 151, compared with the pixel electrode 50 in FIG. 6A. The metal nitride layer 151x does not contain the metallic element 153 at its surface.

The details will be described later, but in the present embodiment, after forming the pixel electrode 50x according to the comparative example, the metallic element 153 is introduced into the vicinity of the top surface 50a of the pixel electrode 50x to form the pixel electrode 50. The steps up to the formation of the pixel electrode 50x according to the comparative example are included in the pixel electrode formation process illustrated in FIG. 2. The subsequent steps of introducing the metallic element 153 and forming the functional layer 53 and photoelectric conversion layer 51, for example, are included in the photoelectric conversion layer formation process. Thus, although not illustrated in FIGS. 6A and 6B, a natural oxide film is formed on the surface of each of the pixel electrodes 50 and 50x due to atmospheric exposure.

Generally, the natural oxide films generated on metal and semiconductor surfaces create surface states derived from compositional defects or dangling bonds. Carrier generation, carrier movement, or carrier generation and movement through surface states inhibits the improvement of device characteristics. Regarding this, the metallic element 153 and its oxides can reduce the surface state density of the natural oxide film present on the surface of the pixel electrode 50. This reduces the effect of the natural oxide film on each device in the silicon wafer 100 and makes the characteristics more uniform, thereby suppressing variations in characteristics. Aluminum oxide (Al₂O₃) deposited on the surface of titanium oxide (TiO₂) in dye-sensitized solar cell systems has been reported to have an effect in that the surface state density on the TiO₂ surface is reduced, as described in Y. Noma et al, “Surface State Passivation Effect for Nanoporous TiO₂ Electrode Evaluated by Thermally Stimulated Current and Application to All-Solid State Dye-Sensitized Solar Cells”, Jpn. J. Appl. Phys., 2008, Vol. 47, No. 1S.

FIG. 7 is a diagram illustrating a threshold voltage defined in a device in which a device structure from the pixel electrode 50 to the top electrode 52 is formed. In FIG. 7, the horizontal axis represents the voltage applied across the pixel electrode 50 and the top electrode 52. The vertical axis represents the current flowing through the top electrode 52 and the pixel electrode 50. As illustrated in FIG. 7, in a case where the voltage applied across the top electrode 52 and the pixel electrode 50 is increased, the voltage value obtained when the current having a reference current value flows is defined as a threshold voltage Vth.

In the case of the comparative example in which the metallic element 153 is not contained, the standard deviation o of the threshold voltage Vth of each device within the plane of a 12-inch silicon wafer 100 was σ=0.040. In contrast, in the case of the embodiment in which the metallic element 153 is contained, the standard deviation o decreases to σ=0.024. In this manner, it can be seen that the variations in the threshold voltage Vth are suppressed, and the variations in characteristics are suppressed within the plane.

Note that the metallic element 153 does not have to be Al as long as the metallic element 153 is expected to have an effect in that dangling bonds, for example, of the metal oxide at the surface of the pixel electrode 50 are suppressed. If substantially the same effect is expected, the metallic element 153 may be Hf, Ni, or the like. Note that the metallic element 153 may be Ti in a case where the pixel electrode 50 contains Ta as its main component.

In the present embodiment, the concentration of the metallic element 153 at the top surface 50a of the pixel electrode 50 is higher than the concentration of the metallic clement 153 at the bottom surface 50b of the pixel electrode 50. That is, the metallic element 153 has a distribution in the pixel electrode 50 such that the metallic element 153 is more abundant near the top surface 50a and less abundant near the bottom surface 50b. Note that the concentration of the metallic element 153 at the top surface 50a is the concentration of the metallic element 153 contained within a predetermined thickness including the top surface 50a. The predetermined thickness is the minimum film thickness required for the analysis limit in secondary ion mass spectrometry (SIMS) or X-ray photoelectron spectroscopy (XPS) analysis using elemental distribution analytical equipment and is, for example, 3 nm.

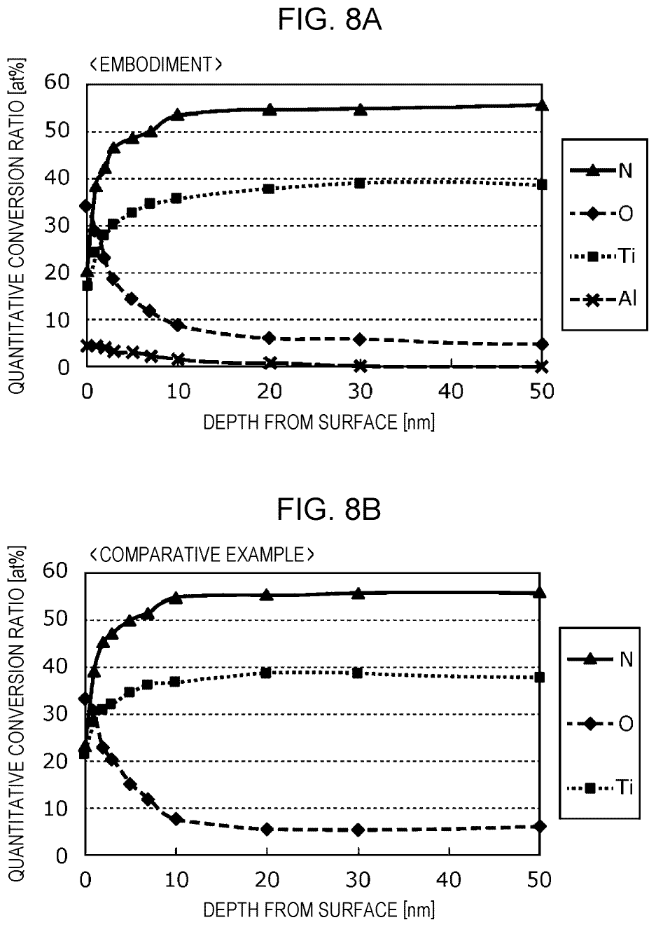

FIGS. 8A and 8B are diagrams illustrating the compositions of the pixel electrodes 50 and 50x according to the embodiment and comparative example, respectively. In each drawing, the horizontal axis represents the depth from the surface. The location with a depth of 0 nm from the surface corresponds to the top surface 50a. The vertical axis represents the quantitative conversion ratio, specifically the elemental concentrations of the contained elements. In this case, each elemental concentration refers to the ratio of the number of atoms of a particular element present in the measurement region to the total number of atoms present in the measurement region. FIGS. 8A and 8B illustrate results from XPS analysis. Note that carbon and fluorine were detected in the acquired XPS spectra, but are not illustrated in the drawings. In the present embodiment, the manufacturing method described later has succeeded in introducing Al at a concentration of approximately 5% into the top surface 50a of the pixel electrode 50 as illustrated in FIG. 8A.

As can be seen by comparing FIGS. 8A and 8B, the distributions of titanium (Ti) and nitrogen (N) are almost identical between the pixel electrodes 50 and 50x. The elemental concentrations of Ti and N are almost constant and stable in the depth range deeper than about 10 nm, whereas the elemental concentrations of Ti and N are lower in the vicinity of the top surface 50a than in deeper portions. In this case, the vicinity of the top surface 50a is the depth range from greater than or equal to 1 nm to less than 10 nm from the top surface 50a.

Instead of lower elemental concentrations of Ti and N, the vicinity of the top surface 50a contains oxygen (O). The elemental concentration of O is almost constant and stable in the depth range deeper than about 10 nm, whereas the elemental concentration of O is higher in the vicinity of the top surface 50a than in deeper portions. In the pixel electrode 50x according to the comparative example, this oxygen is caused by the natural oxide film. The pixel electrode 50 according to the embodiment contains, as oxygen, oxygen originating from the natural oxide film and oxygen originating from the oxide film (Al₂O₃) of the deposited metallic element 153.

Note that a high content of the metallic element 153 in the pixel electrode 50 may degrade various characteristics of the image sensor 101. Therefore, the degradation of the characteristics can be suppressed by reducing the content of the metallic element 153 to below a predetermined amount. In a case where the content of the metallic element 153 is too small, the above-mentioned suppression of variations in the characteristics cannot be fully achieved. Thus, for example, in the pixel electrode 50 according to the embodiment, the elemental concentration of the metallic element 153 (for example, Al) at the top surface 50a is greater than or equal to 0.5% and less than or equal to 10%. This can suppress the above-described variations in the characteristics and also suppress the degradation of the characteristics of the image sensor 101.

The elemental concentration of the metallic element 153 at the bottom surface 50b is less than or equal to 0.5%. That is, by preventing the metallic element 153 from being introduced deep into the pixel electrode 50, the degradation of the characteristics of the image sensor 101 can be suppressed.

In the present embodiment, as illustrated in FIG. 6A, the pixel electrode 50 has a multilayer structure formed by the metal nitride layer 151 and the metal layer 152. This can prevent the metallic element 153 introduced from the top surface 50a from penetrating the pixel electrode 50 and diffusing into the interlayer insulating layer 43C and other layers.

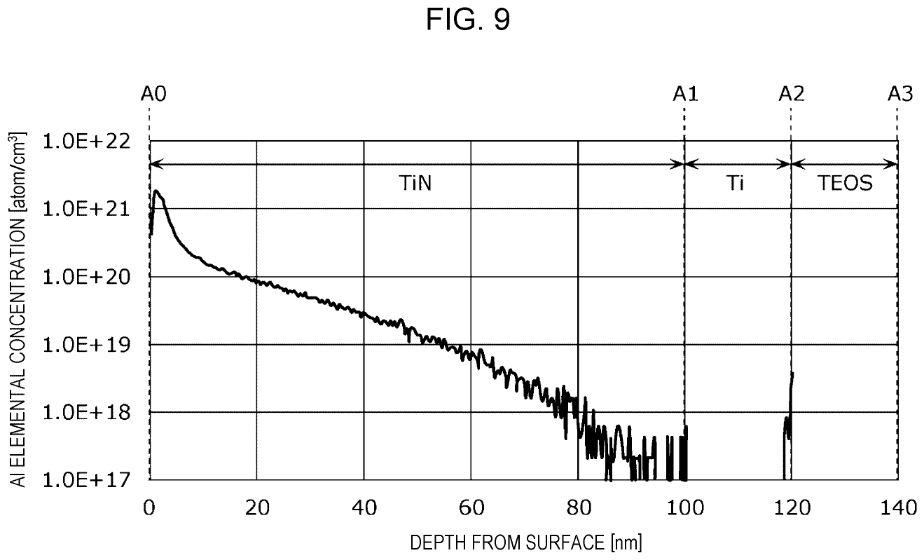

FIG. 9 is a diagram illustrating the Al composition of the pixel electrode 50 of the image sensor 101 according to the embodiment. In FIG. 9, the horizontal axis represents the depth from the surface of the pixel electrode 50, and the vertical axis represents Al elemental concentration. Specifically, FIG. 9 illustrates the SIMS spectrum of the pixel electrode 50 according to the embodiment illustrated in FIG. 6A. A0, A1, A2, and A3 illustrated in FIG. 9 correspond to A0, A1, A2, and A3 illustrated in FIG. 6A, respectively. Specifically, A0 represents the top surface 50a of the pixel electrode 50, namely the location where the depth from the surface is 0 nm. A1 represents the location of the interface between the metal nitride layer 151 and the metal layer 152. In this case, the film thickness of the metal nitride layer 151 is 100 nm. A2 represents the location of the bottom surface 50b of the pixel electrode 50. In this case, the film thickness of the metal layer 152 is 20 nm. A3 represents the location where the depth from the top surface (the location denoted by A2) of the interlayer insulating layer 43C is 20 nm.

As illustrated in FIG. 9, the concentration of Al at A0 is higher than the concentration of Al at A1 and higher than the concentration of Al at A2. That is, the concentration of Al at the top surface 50a of the pixel electrode 50 is higher than the concentration of Al at the interface between the metal nitride layer 151 and the metal layer 152 and higher than the concentration of Al at the bottom surface 50b of the pixel electrode 50. It can be seen that Al introduced from the top surface 50a of the pixel electrode 50 is mostly distributed within the metal nitride layer 151 and is practically absent in the metal layer 152. In this manner, by causing the pixel electrode 50 to have a multilayer structure, Al can be prevented from reaching the bottom surface 50b of the pixel electrode 50. The metallic element 153, such as Al, can be effectively contained in the vicinity of the top surface 50a of the pixel electrode 50.

The metallic element 153 introduced into the top surface 50a of the pixel electrode 50 can reduce the parasitic light sensitivity of the image sensor 101.

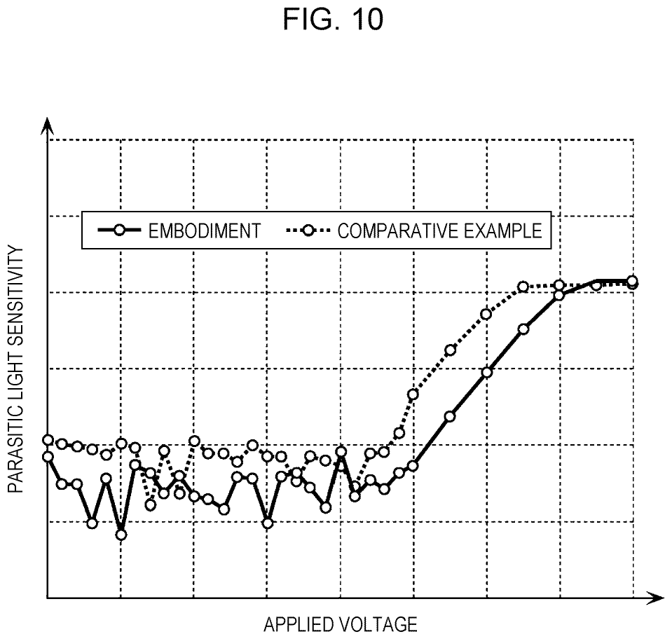

FIG. 10 is a diagram illustrating the relationships between parasitic light sensitivity and applied voltage for the image sensors according to the embodiment and comparative example. In FIG. 10, the horizontal axis represents the applied voltage applied to the top electrode 52, and the vertical axis represents parasitic light sensitivity.

As illustrated in FIG. 10, in both the embodiment and the comparative example, the parasitic light sensitivity is kept low in a case where the applied voltage is low, whereas the parasitic light sensitivity increases when the applied voltage is high. Since high parasitic light sensitivity is a source of noise, the longer the range over which the parasitic light sensitivity is kept low, the better the image sensor's imaging performance will be.

As illustrated in FIG. 10, when the embodiment and the comparative example are compared with each other, the applied voltage at the rise of parasitic light sensitivity is higher in the embodiment than in the comparative example. That is, according to the embodiment, it can be seen that the parasitic light sensitivity is kept low over a wider range of applied voltages. This is expected due to the fact that the metallic element 153 has a lower work function than the first metal contained as the main component of the pixel electrode 50.

In this manner, by containing the metallic element 153 whose work function is lower than that of the first metal at the surface of the pixel electrode 50, the characteristics of the image sensor 101 can be further improved. That is, not only can variations in characteristics be suppressed, but the effect of reducing parasitic light sensitivity can also be obtained.

### [Image Sensor Manufacturing Method]

Next, a manufacturing method of the image sensor 101 according to the present embodiment will be described. In the following, in the manufacturing method of the image sensor 101 according to the present embodiment, the steps in and after the formation of the characteristic pixel electrode 50 will be described in more detail. Known methods can be used for forming impurity regions in the semiconductor substrate 31 and for forming interlayer insulating layers and wiring layers.

### (A) Steps for Forming Pixel Electrodes 50x

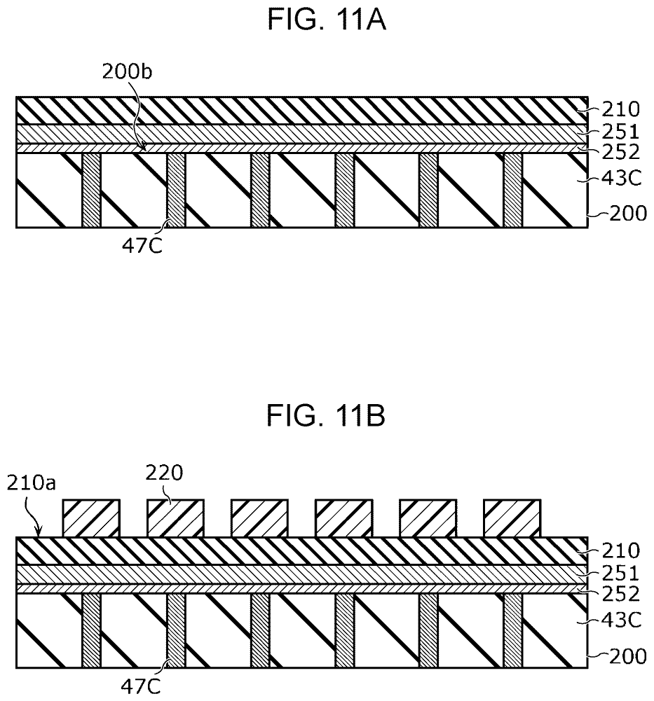

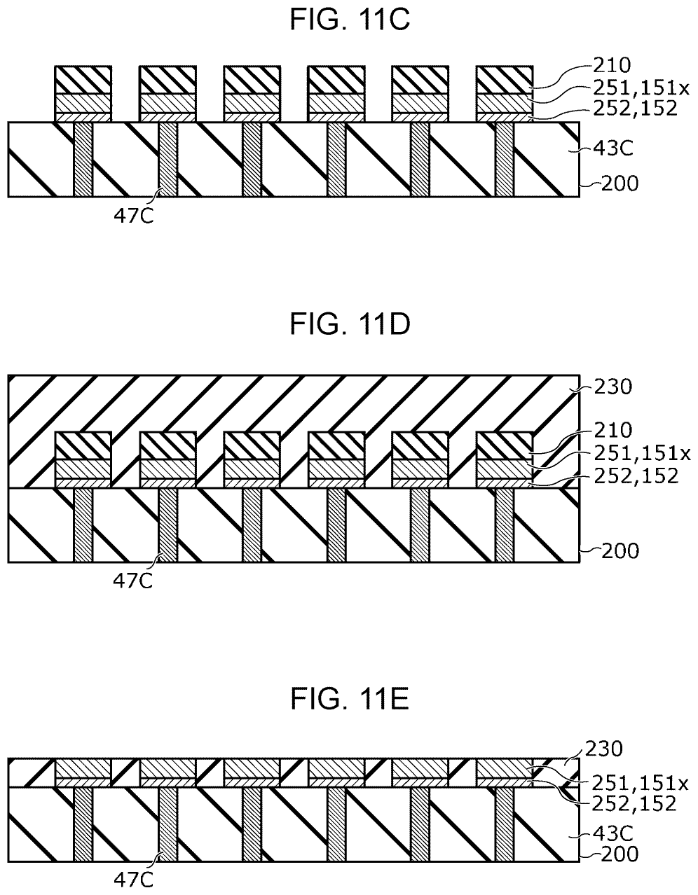

First, the steps for forming pixel electrodes 50x before introducing the metallic element 153 will be described using FIGS. 11A to 11E. FIGS. 11A to 11E are cross-sectional views for illustrating the steps for forming the pixel electrodes 50x in the manufacturing method of the image sensor 101 according to the present embodiment. Note that, in FIGS. 11A to 11E, the illustration of constituent elements, such as the semiconductor substrate 31, located below the interlayer insulating layer 43C is omitted.

Note that, in the following, an example will be illustrated in which each pixel electrode 50 has a multilayer structure formed by Ti and TiN; however, the pixel electrode 50 can be formed in the same way when the pixel electrode 50 has a multilayer structure formed by Ta and TaN. Moreover, in a case where the pixel electrode 50 has a single layer structure formed by TiN or TaN, it is sufficient that the formation of a single layer formed by Ti or Ta be omitted.

First, as illustrated in FIG. 11A, before forming the pixel electrodes 50, the plugs 47C and the interlayer insulating layer 43C are exposed at the top surface 200b of the substrate 200. A titanium layer 252 and a titanium nitride layer 251 are formed over the entire surface of the substrate by continuously depositing, using a sputtering method, titanium and titanium nitride on the top surface 200b of the substrate 200. Tetraethyl orthosilicate (TEOS) is then deposited over the entire surface of the substrate using a chemical vapor deposition (CVD) method to form an insulating layer 210.

Next, as illustrated in FIG. 11B, resist is applied to a top surface 210a of the insulating layer 210 and is sensitized and exposed to light using a photomask so that the resist remains on the portions where the pixel electrodes 50 are to be formed. Thereafter, a resist pattern 220 is developed using a developing solution.

As illustrated in FIG. 11C, etching is then performed to remove the insulating layer 210, the titanium nitride layer 251, and the titanium layer 252 except for the portion where the resist pattern 220 is deposited. Thereafter, the resist pattern 220 is removed by ashing. The titanium layer 252 patterned to have a predetermined shape corresponds to the metal layer 152 illustrated in FIG. 6A. The titanium nitride layer 251 patterned to have a predetermined shape corresponds to the metal nitride layer 151x illustrated in FIG. 6B. That is, at this point, the second metal has not yet been introduced into the surface of the metal nitride layer 151x.

After etching is completed, as illustrated in FIG. 11D, tetraethyl orthosilicate (TEOS) is again deposited over the entire surface of the substrate using a chemical vapor deposition (CVD) method to form an insulating layer 230 to bury the insulating layer 210, the titanium nitride layer 251, and the titanium layer 252.

Lastly, as illustrated in FIG. 11E, the insulating layer 230 and the titanium nitride layer 251 are polished using a chemical-mechanical polishing (CMP) method to expose the titanium nitride layer 251.

Through this series of processes, the pixel electrodes 50x are formed without the introduction of the second metal into the surfaces thereof.

Note that the control electrodes 58 can be formed using the same processes used to form the pixel electrodes 50x. That is, the pixel electrodes 50x and the control electrodes 58 can be formed simultaneously through the same steps.

The steps up to the formation of the pixel electrodes 50x correspond to the pixel electrode formation process illustrated in FIG. 2. After the pixel electrodes 50x are formed, the substrate 200 is moved between apparatuses to perform the photoelectric conversion layer formation process and is exposed to the atmosphere. In this step, a natural oxide film is formed on the surfaces of the pixel electrodes 50x.

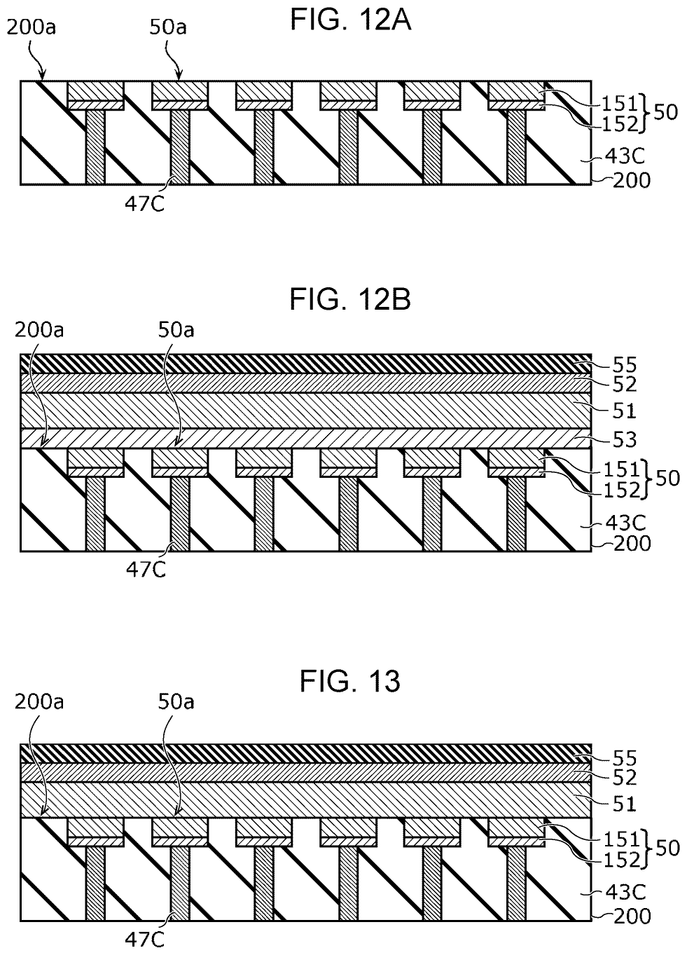

In the following, the steps in the photoelectric conversion layer formation process will be described using FIGS. 12A and 12B. FIGS. 12A and 12B are cross-sectional views for illustrating the steps in the photoelectric conversion layer formation process in the manufacturing method of the image sensor 101 according to the present embodiment. In FIGS. 12A and 12B, similarly to as in FIG. 5, the substrate 200 and insulating layer 230 illustrated in FIG. 11E are collectively illustrated as a substrate 200.

### (B) Step for Introducing Metallic Element 153

Next, the step for introducing the metallic element 153 into the surfaces of the pixel electrodes 50x will be described.

An Al₂O₃ layer is formed on the top surface 200a of the substrate 200 using an atomic layer deposition (ALD) method to cover at least the top surfaces 50a of the pixel electrodes 50x. As a result, as illustrated in FIG. 12A, the pixel electrodes 50 are formed in which the metallic element 153 is introduced into the surfaces of the pixel electrodes 50. Examples of methods for fabricating a layer for introducing the metallic element 153 include atomic layer deposition (ALD) and chemical vapor deposition (CVD) methods. For example, an Al₂O₃ layer having a thickness of 0.5 nm is formed using an ALD method.

By forming an Al₂O₃ layer, trimethylaluminum, a precursor of Al₂O₃, diffuses into the grain boundaries of the pixel electrodes 50, and the metallic element 153 or its oxide is introduced into the vicinity of the top surfaces 50a of the pixel electrodes 50.

In the step of introducing the metallic element 153, once the Al₂O₃ layer is deposited with a thickness of greater than or equal to 0.5 nm, and thereafter the thickness of the Al₂O₃ layer may be reduced or the Al₂O₃ layer may be removed by physically or chemically thinning the Al₂O₃ layer. For example, the Al₂O₃ layer is thinned or removed by wet etching, dry etching, or polishing such as CMP. Even in a case where the Al₂O₃ layer is removed to the extent of the deposited film's thickness, Al can still be introduced into the top surface 50a of the pixel electrode 50.

In this manner, the metallic element 153 or its oxide can be introduced into the top surfaces 50a of the pixel electrodes 50. Note that the film thickness of the Al₂O₃ layer is, for example, less than or equal to 5 nm. This allows the Al₂O₃ layer to transmit electrons therethrough due to the tunneling effect. That is, the pixel electrodes 50 can be caused to collect the electric charge generated in the photoelectric conversion layer 51.

Note that, instead of the Al₂O₃ layer, a HfO₂ layer may be formed. Even in a case where a HfO₂ layer is formed, substantially the same effect as the Al₂O₃ layer can be obtained.

### (C) Step for Forming Functional Layer 53

Next, as illustrated in FIG. 12B, the functional layer 53 is formed by depositing an organic semiconductor material on the top surfaces 50a of the pixel electrodes 50, which include the metallic element 153, using a vacuum deposition method to cover at least the pixel electrodes 50. The organic semiconductor material is, for example, a material that realizes the functions required for the functional layer 53, such as an electric charge blocking function. Note that the functional layer 53 may be formed by a spin coating method, an ink-jet printing method, a die coating method, a spray coating method, a screen printing method, or other methods instead of the vacuum deposition method.

### (D) Step for Forming Photoelectric Conversion Layer 51

Next, as illustrated in FIG. 12B, the photoelectric conversion layer 51 is formed by depositing an organic semiconductor material, which has a photoelectric conversion function, on the top surface of the functional layer 53 using a vacuum deposition method to cover at least the pixel electrodes 50. Note that the photoelectric conversion layer 51 may be formed by a spin coating method, an ink-jet printing method, a die coating method, a spray coating method, a screen printing method, or other methods instead of the vacuum deposition method.

### (E) Step for Forming Top Electrode 52

Next, as illustrated in FIG. 12B, the top electrode 52 is formed by depositing ITO on the top surface of the photoelectric conversion layer 51 using a sputtering method. Note that the top electrode 52 is formed at least on the region of the photoelectric conversion layer 51 corresponding to the region where the pixel electrodes 50 are provided.

### (F) Step for Forming Protection Layer 55

Next, as illustrated in FIG. 12B, Al₂O₃ is formed on the top surface of the top electrode 52 using an atomic layer deposition (ALD) method. The protection layer 55 is formed at least on the region of the top electrode 52 corresponding to the region where the pixel electrodes 50 are provided. Note that the protection layer 55 may also be formed using a chemical vapor deposition (CVD) method, a sputtering method, or other methods instead of an atomic layer deposition (ALD) method.

Thereafter, after patterning or the like is performed on each layer as necessary, the image sensor 101 illustrated in FIG. 5 can be formed by forming the metal connectors 57, the pixel protection film 56, the color filters 60, and the microlenses 61.

Note that the light detection unit 10 does not have to include the functional layer 53. FIG. 13 is a cross-sectional view for illustrating the steps for forming the light detection unit 10 that does not include the functional layer 53 in the manufacturing method of an image sensor according to the present embodiment.

The steps up to the formation of the pixel electrodes 50x are as described using FIGS. 11A to 11E. After the pixel electrodes 50x are formed, a natural oxide film is formed due to atmospheric exposure.

An Al₂O₃ layer or a HfO₂ layer is formed on the top surface 200a of the substrate 200 using an atomic layer deposition (ALD) method to cover at least the top surfaces 50a of the pixel electrodes 50x. As a result, as illustrated in FIG. 6A, the pixel electrodes 50 are formed in which the metallic element 153 is introduced into the surfaces of the pixel electrodes 50. Examples of methods for fabricating a layer for introducing the metallic element 153 include atomic layer deposition (ALD) and chemical vapor deposition (CVD) methods.

After the Al₂O₃ layer or HfO₂ layer is formed, the photoelectric conversion layer 51 is formed, without forming the functional layer 53, by depositing an organic semiconductor material having a photoelectric conversion function on the top surfaces 50a of the pixel electrodes 50, which include the metallic element 153, using a vacuum deposition method to cover at least the pixel electrodes 50. Note that the photoelectric conversion layer 51 may be formed by a spin coating method, an ink-jet printing method, a die coating method, a spray coating method, a screen printing method, or other methods instead of the vacuum deposition method.

As described above, in the image sensor 101 according to the present embodiment, even via a process that requires atmospheric exposure after the formation of the pixel electrodes 50, the formation of a metal oxide film on the top surfaces 50a of the pixel electrodes 50 is expected to suppress carrier trap levels caused by dangling bonds or the like present in the natural oxide film generated on the top surfaces 50a of the pixel electrodes 50 due to atmospheric exposure. This can reduce variations in characteristics due to differences in atmospheric exposure time or differences in the deposition situations of each device within the silicon wafer surface. Thus, the image sensor 101 can be fabricated at low cost by achieving manufacturing steps with smaller variations in the characteristics of each device within the silicon wafer plane, without using costly manufacturing processes such as forming the image sensor 101 and performing all of the transport between the processes under an inert atmosphere or vacuum without exposing the silicon wafer to the atmosphere at all.

### Other Embodiments

As described above, the imaging devices according to one or more embodiments have been described; however, the present disclosure is not limited to these embodiments. Without departing from the gist of the present disclosure, examples obtained by adding various modifications conceived by one skilled in the art to the embodiments and forms constructed by combining constituent elements in different embodiments are also included in the scope of the present disclosure.

For example, in the above-described embodiments, an example has been

illustrated in which each pixel electrode 50 has a multilayer structure formed by the metal nitride layer 151 and the metal layer 152, but the present disclosure is not limited to this. The pixel electrode 50 may have a single layer structure formed by the metal nitride layer 151.

For example, in the above-describe embodiments, the function of photoelectric conversion is realized using an organic film, but substantially the same effect can be expected using inorganic materials, such as silicon, germanium, or selenium, or composite materials of organic and inorganic materials such as perovskite materials and quantum dots. Thus, the photoelectric conversion material is not limited to organic materials, but can also be inorganic materials or composite materials of organic and inorganic materials.

In addition, various changes, replacements, additions, omissions, and the like can be made to each of the above-described embodiments within the scope of the claims or their equivalents.

The present disclosure may be suitably used in image sensors for various applications, such as cameras or distance measurement devices.

What is claimed is:

1. An imaging device comprising:
a pixel electrode having a first plane and a second plane that faces the first plane;
a photoelectric converter that is in contact with the first plane and converts light into electric charge; and
a counter electrode that faces the first plane of the pixel electrode with the photoelectric converter interposed therebetween, wherein
the pixel electrode contains a nitride of a first metal, and a second metal different from the first metal,
the nitride of the first metal is a main component of the pixel electrode,
a concentration of the second metal in a first three-dimensional region including the first plane is higher than a concentration of the second metal in a second three-dimensional region including the second plane,
the first three-dimensional region does not include the second plane, and
the second three-dimensional region does not include the first plane.

2. The imaging device according to claim 1,
wherein the second metal is aluminum.

3. The imaging device according to claim 1,
wherein the pixel electrode contains oxygen at the first plane.

4. The imaging device according to claim 1,
wherein the first metal is titanium.

5. The imaging device according to claim 1,
wherein an elemental concentration of the second metal in the first three-dimensional region is greater than or equal to 0.5% and less than or equal to 10%.

6. The imaging device according to claim 1, wherein
the pixel electrode includes
a first layer that contains the nitride of the first metal, and
a second layer that contains the first metal, and
the first layer and the second layer are stacked in this order in a direction from the first plane toward the second plane.

7. The imaging device according to claim 1,
wherein an elemental concentration of the second metal in the second three-dimensional region is less than or equal to 0.5%.

8. The imaging device according to claim 1,
wherein the photoelectric converter contains an organic material.

9. The imaging device according to claim 1,
wherein the first three-dimensional region does not include a third plane, which is located equidistant from the first and second planes, and the second three-dimensional region does not include the third plane.

10. The imaging device according to claim 1, wherein
a first thickness of the first three-dimensional region is 10 nm, and a second thickness of the second three-dimensional region is 10 nm, and
a direction of the first thickness and a direction of the second thickness are parallel to a direction perpendicular to both the first plane and the second plane.
